(19) United States
(12) Patent Application Publication
(10) Pub. No.: US 2014/0264497 A1
(43) Pub. Date: Sep. 18, 2014

(54) SELF-ALIGNED APPROACH FOR DRAIN DIFFUSION IN FIELD EFFECT TRANSISTORS

(71) Applicant: International Business Machines Corporation, Armonk, NY (US)

(72) Inventors: Chung H. Lam, Peekskill, NY (US); Jing Li, Ossining, NY (US)

(73) Assignee: International Business Machines Corporation, Armonk, NY (US)

(21) Appl. No.: 14/037,253

(22) Filed: Sep. 25, 2013

Related U.S. Application Data
(63) Continuation of application No. 13/833,989, filed on Mar. 15, 2013.

(51) Int. Cl. H01L 21/225; H01L 29/66; H01L 29/78

(52) U.S. Cl. CPC H01L 21/225; H01L 29/78; H01L 29/66477
USPC 257/288; 438/559

(57) ABSTRACT

A method for doping terminals of a field-effect transistor (FET), the FET including a drain region, a source region, and a surround gate surrounding a channel region, the method including depositing a dopant-containing layer, such that the surround gate prevents the dopant-containing layer from contacting the channel region of the FET, the dopant-containing layer including a dopant. The dopant then diffuses the dopant from the dopant-containing layer into at least one of the drain region and source region of the FET.

### CROSS-REFERENCE TO RELATED APPLICATIONS

This application claims priority under 35 U.S.C. §120 to U.S. patent application Ser. No. 13/833,989 filed Mar. 15, 2013, the entire text of which is specifically incorporated by reference herein.

### BACKGROUND

This invention relates to memory cells in integrated circuits, and more particularly to the fabrication of field effect transistors.

Emerging non-volatile memory technologies such as phase change memory (PCM), relative random access memory (RRAM), and spin-transfer torque random access memory (STT RAM) call for a selector device with a small footprint and high current drive capability. Vertical surround gate field effect transistor (VSG FET) devices are an optimal selector candidate for these non-volatile memory technologies.

In such memory devices, bitline capacitance is strongly related to the data patterns stored in each cell on the same bit line. The optimization of the gate-to-drain overlap capacitance is important for memory performance, since gate-to-drain overlap capacitance is the major contributor to bitline (BL) capacitance. Control of Miller capacitance is also important in order to control variability in bitline capacitance.

### BRIEF SUMMARY

Accordingly, one aspect of the present invention is a method for doping terminals of a field-effect transistor (FET). The FET includes a drain region, a source region, and a surround gate surrounding a channel region. The method includes depositing a dopant-containing layer such that the surround gate prevents the dopant-containing layer from contacting the channel region of the FET, with the dopant-containing layer including a dopant. The method includes a diffusing step that diffuses the dopant from the dopant-containing layer into drain region and/or source region of the FET.

Another aspect of the present invention is a field-effect transistor (FET). The FET includes a drain region, a source region, and a surround gate surrounding a channel region. The FET prepared by a process including depositing a dopant-containing layer that includes a dopant such that the surround gate prevents the dopant-containing layer from contacting the channel region of the FET. Next the dopant is diffused from the dopant-containing layer into the drain region and/or source region of the FET.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawing in which:

FIG. 1 shows a method for doping terminals of a field-effect transistor (FET), the FET including a drain region, a source region, and a surround gate surrounding a channel region, in accordance with one embodiment of the invention.

FIG. 2 shows an n-dopant-containing layer deposition step, in accordance with one embodiment of the invention.

FIG. 3 shows a capping layer deposition step, in accordance with one embodiment of the invention.

FIG. 4 shows a diffusion step, in accordance with one embodiment of the invention.

FIG. 5 shows a removal step, in accordance with one embodiment of the invention.

### DETAILED DESCRIPTION

The present invention is described with reference to embodiments of the invention. Throughout the description of the invention reference is made to FIG. 1. When referring to the figures, like structures and elements shown throughout are indicated with like reference numerals.

FIG. 1 shows a method for doping terminals of a field-effect transistor (FET), the FET including a drain region, a source region, and a surround gate surrounding a channel region, in accordance with one embodiment of the invention.

The method includes a deposition step 102. During deposition step 102, a dopant-containing layer 202 is deposited onto the FET, as shown in FIG. 2. In one embodiment, the FET is a vertical surround gate field effect transistor (VSG FET) 200. The surround gate 204 of the FET prevents the dopant-containing layer 202 from contacting the channel region 204.

The channel region 208 may be a first portion of a polysilicon column separated from the surround gate 204 by a silicon oxide film. The drain region 210 may be a second portion of the polysilicon column surrounded by the dopant-containing layer 202. Furthermore, the surround gate 204 of the FET may surround the channel region 208 of the FET along a vertical direction or along a horizontal direction. The surround gate 204 may also surround the channel laterally.

During the deposition step 102, the dopant in the dopant-containing layer 202 may be an n-type dopant. The dopant-containing layer 202 may comprise, for example, arsenosilicate glass (ASG). Furthermore, the deposition step 102 may be performed using an isotropic deposition process.

According to one embodiment of the invention, the FET may be in the form of a nanowire. The deposition step may involve conformal ASG deposition. In one embodiment, the dopant-containing layer may be 100 to 500 angstroms in thickness.

According to another embodiment of the invention, the deposition step may be performed after etching of polysilicon columns. The deposition step may also be performed after cleaning the polysilicon columns and the gate. In one embodiment, the deposition step is performed on a partially formed FET where the elements to be doped, for example the gate and the drain elements, are exposed. In this way, the deposition step causes the dopant-containing layer 202 to come into direct contact with the terminal to be doped. The elements which are not to be doped may be covered or masked with a capping layer prior to the deposition step.

The polysilicon column may be doped with p-type dopant, such as boron, for example at a dopant concentration of around 17- or 18-atoms per cubic centimeter. During the diffusion step, boron in the polysilicon pillar may diffuse into the n-type dopant-containing layer 202.

Returning to FIG. 1, after deposition step 102 is completed, the method continues to capping step 104. At capping step 104, a capping layer 212 is deposited over the dopant-containing layer 202, as shown in FIG. 3. The capping layer may be a layer of tetraethylorthosilicate (TEOS). According to one embodiment of the invention capping step 104 may be performed using a chemical vapor deposition (CVD) procedure.

Returning to FIG. 1, after capping step 104 is completed, the method proceeds to diffusing step 106. Accordingly, the diffusing step 106 may also hereinafter be referred to as a drive-in step.

At diffusing step 106, the dopant diffuses from the dopant-containing layer 202 into at least one of the drain region 206 and source region 210 of the FET. According to one embodiment of the invention, during diffusing step 106, the dopant in the dopant-containing layer 202 diffuses from into the drain region 206, as shown in FIG. 4. The dopant may be introduced to the drain 206 and/or source 210 terminals by outdiffusion from a dopant-containing layer 202. Diffusing step 106 may involve heating the dopant-containing layer 202 at a temperature of at least 500° C., for example at a temperature between 900° C. to 1100° C. Diffusion step 106 may also involve heating the dopant-containing layer 202 for at least 15 minutes.

According to another one embodiment of the invention, diffusing step 106 may result in doped FET terminals at a n-type dopant concentration of around 10²⁰ atoms per cubic centimeter.

According to yet another embodiment of the invention, heating the TEOS layer will result in its breakdown to silicon dioxide and other components. In one embodiment, diffusing step 106 may involve heating the dopant-containing layer 202 in a nitrogen atmosphere.

As shown in FIG. 4, the dopant-containing layer 202 may be in direct contact to one or more polysilicon columns. The polysilicon columns may be used as spacers to define the FET's drain doping profile.

Returning to FIG. 1, after diffusing step 106 is completed, the method proceeds to removal step 108. Accordingly, removal step 108 may also hereinafter be referred to as a stripping step. At the removal step 108, the dopant-containing layer 202 and the capping layer 212 are removed from the doped FET, as shown in FIG. 5. According to one embodiment of the invention, the stripping step may be performed using hydrofluoric acid (HF).

The method may result in self-aligned terminals such that underlap and/or overlap between the gate and the drain, or between the gate and the source, is minimized.

According to one embodiment of the invention, the method for doping terminals may be applied to FETs after polysilicon gate formation. According to another embodiment of the invention, the polysilicon gate may also doped by the same process, which may be used to reduce wordline (WL) resistance.

In accordance with another embodiment of the invention, a field-effect transistor (FET) includes a drain region 206, a source region 210, and a surround gate 204 surrounding a channel region 208 may also be prepared using process shown in FIG. 2.

The process for preparing the FET involves a deposition step 102. During the deposition step 102, a dopant-containing layer is deposited onto the FET. The surround gate 204 of the FET prevents the dopant-containing layer 202 from contacting the channel region 208. The surround gate 204 may surround the channel region 208 of the FET along a vertical direction or along a horizontal direction. After the deposition step 102 is complete, the process proceeds to the capping step 104.

In accordance with one embodiment of the invention, the FET may be formed over a silicon oxide layer. In another embodiment, the FET may be formed on top of a previously constructed FET layer.

At the capping step 104, a capping layer 212 is deposited over the dopant-containing layer 202. After the capping step 104 is complete, the process proceeds to the diffusion step 106.

At the diffusing step 106, the dopant from the dopant-containing layer is diffused by heating the dopant-containing layer 202 at a temperature of at least 500° C. for at least 15 minutes. After the diffusing step 106 is complete, the process proceeds to the removal step 108.

At the removal step 108, the dopant-containing layer 202 and the capping layer 212 are removed from the doped FET.

According to one embodiment of the invention, after the removal step, a memory element may be placed on top of the drain element. After placing the memory element, a bitline contact or wordline contact may be placed on top of the memory element. In an alternative embodiment of the invention, the bitline or wordline contact is added after the removal step. A memory element may then be added after the bitline or wordline contact has been added. According to one embodiment of the invention, the wordline and bitline FETs may not be in direct contact with each other.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A field-effect transistor (FET) with a drain region, a source region, and a surround gate surrounding a channel region, the FET prepared by a process comprising the steps of:
depositing a dopant-containing layer such that the surround gate prevents the dopant-containing layer from contacting the channel region of the FET, the dopant-containing layer including a dopant; and
diffusing the dopant from the dopant-containing layer into at least one of the drain region and source region of the FET.

2. The FET of claim 1, wherein the surround gate surrounds the channel region of the FET along a vertical direction.

3. The FET of claim 1, wherein the surround gate surrounds the channel region of the FET along a horizontal direction.

4. The FET of claim 1, prepared by a process further comprising:
depositing a capping layer over the dopant-containing layer prior to diffusing the dopant; and
removing the dopant-containing layer and the capping layer after diffusing the dopant from the dopant-containing layer.

5. The FET of claim 1, wherein diffusing the dopant from the dopant-containing layer comprises heating the dopant-containing layer at a temperature of at least 500° C. for at least 15 minutes.
